(19) United States
(12) Patent Application Publication
(10) Pub. No.: US 2023/0027336 A1
(43) Pub. Date: Jan. 26, 2023

(54) EVAPORATION APPARATUS, SUBLIMATION PURIFICATION APPARATUS, ORGANIC ELECTRONIC DEVICE PRODUCTION METHOD, AND SUBLIMATION PURIFICATION METHOD

(71) Applicant: Fukuoka Industry, Science & Technology Foundation, Fukuoka-shi, Fukuoka (JP)

(72) Inventors: Shinichiro Kobayashi, Fukuoka-shi, Fukuoka (JP); Kengo Takeda, Tokyo (JP); Hiroshi Miyazaki, Fukuoka-shi, Fukuoka (JP)

(21) Appl. No.: 17/781,618

(22) PCT Filed: Nov. 27, 2020
(86) PCT No.: PCT/JP2020/044341

§ 371 Date: Jun. 1, 2022

(30) Foreign Application Priority Data
Dec. 2, 2019 (JP) 2019-217931

(51) Int. Cl. H05B 6/10; H05B 6/04

(52) U.S. Cl. CPC H05B 6/108; H05B 6/04

(57) ABSTRACT

Provided is an evaporation apparatus configured to form an organic layer made from organic material on a substrate, the apparatus including: a container configured to contain the organic material, at least a portion of which is composed of conductor; a heating coil disposed around the container; a DC power supply; an inverter connected to the DC power supply; a primary coil connected to the inverter; and a secondary coil connected to the heating coil, wherein the primary coil and the secondary coil form a matching transformer.

### TECHNICAL FIELD

The present invention relates to an evaporation apparatus, a sublimation purification apparatus, an organic electronic device production method, and a sublimation purification method, and more particularly, to an evaporation apparatus for depositing an organic material on a substrate.

### BACKGROUND ART

The inventors of the present application have proposed evaporation apparatuses for depositing organic material on a substrate, which is a practical evaporation apparatus for depositing the organic material by suppressing noise while employing an induction heating method excellent in thermal response (Patent Document 1). The induction heating system is superior in thermal response to the resistance heating system. Therefore, heating up and cooling down can be performed quickly, and precise temperature control can be performed.

### PRIOR ART LITERATURE

### Patent Document

Patent Document 1: Japanese Patent Application No. 2018-063368
Patent Document 2: Japanese Patent Application No. 2018-225361
Patent Document 3: Japanese Patent Application No. 2018-225362
Patent Document 4: Japanese Patent Application No. 2018-225363
Patent Document 5: Japanese Patent Application No. 2018-225364

### SUMMARY OF THE INVENTION

### Problem Solved by the Invention

However, in order to heat an induction coil used for induction heating, it is necessary to flow a large current. Then, so much load is applied to the circuit that there is a concern that the temperature goes too high. If the circuit becomes hot, the effect of heat may also be exerted in the chamber, which may impair the excellent thermal response of the induction heating system.

Therefore, the present invention aims to provide a practical evaporation apparatus or the like for suppressing the load of the circuit while flowing a large current by adopting an induction heating method.

### Means for Solving the Problems

A first aspect of the present invention is an evaporation apparatus configured to form an organic layer made from organic material on a substrate, the apparatus comprising a container configured to contain the organic material, at least a portion of which is composed of conductor, a heating coil disposed around the container, a direct current (DC) power supply, an inverter connected to the DC power supply, a primary coil connected to the inverter, and a secondary coil connected to the heating coil, wherein the primary coil and the secondary coil form a matching transformer.

A second aspect of the present invention is the evaporation apparatus of the first aspect, wherein the inverter is included in a power supply unit, wherein the primary coil is closer to a vacuum chamber of the evaporation apparatus than to the power supply unit; and wherein the power supply unit and the primary coil are connected by a coaxial cable.

A third aspect of the present invention is the evaporation apparatus according to the first or second aspect, wherein a winding density of the primary coil is larger than a winding density of the secondary coil.

A fourth aspect of the present invention is the evaporation apparatus according to any one of the first through third aspects, wherein a secondary circuit which is a closed circuit having the secondary coil is a resonant circuit.

A fifth aspect of the present invention is the evaporation apparatus according to any one of the first through fourth aspects, wherein a primary circuit which is a closed circuit having the primary coil is a full-bridge type circuit, in which both ends of the primary coil are connected to the inverter.

A sixth aspect of the present invention is the evaporation apparatus according to any one of the first through fourth aspects, wherein a primary circuit which is a closed circuit having the primary coil is a half-bridge type circuit, in which an end of the primary coil opposite to an end connected to the inverter is grounded via a capacitor connected to the primary coil in series.

A seventh aspect of the present invention is the evaporation apparatus of the sixth aspect, wherein a capacitance of the capacitor is such that a resonant frequency of the primary circuit is different from a resonant frequency of the secondary circuit.

An eighth aspect of the present invention is the evaporation apparatus according to the sixth or seventh aspect, wherein the capacitance C₁ of the capacitor is equal to or larger than a value represented by an equation (1), wherein R₁ is a resistance component of the primary circuit, R₂ is a resistance component of a secondary circuit which is a closed circuit having the secondary coil, ωᵣₑₛ is a resonant angular frequency of the secondary circuit, n₁ is a number of turns of the primary coil, and n₂ is a number of turns of the secondary coil.

$$[ Equation 1 ]$$

$${C}_{1} = {{ω}_{res}^{- 1} [ {R}_{1} + {( \frac{{n}_{1}}{{n}_{2}} )}^{2} {R}_{2} ]}^{- 1} \qquad ( 1 )$$

A ninth aspect of the present invention is the evaporation apparatus according to the sixth or seventh aspect, wherein the resonant angular frequency ωᵣₑₛ of the secondary circuit is equal to or larger than a value represented by an equation (2), wherein C₁ is the capacitance of the capacitor, R₁ is a resistance component of the primary circuit, R₂ is a resistance component of a secondary circuit which is a closed circuit having the secondary coil, n₁ is a number of turns of the primary coil, and n₂ is a number of turns of the secondary coil.

$$[ Equation 2 ]$$

$${ω}_{res} = {{C}_{1}^{- 1} [ {R}_{1} + {( \frac{{n}_{1}}{{n}_{2}} )}^{2} {R}_{2} ]}^{- 1} \qquad ( 2 )$$

A tenth aspect of the present invention is the evaporation apparatus according to any one of the first through ninth aspects, wherein the alternating current supplied to the matching transformer has a high frequency of 200 kHz or more.

The eleventh aspect of the present invention is the evaporation apparatus according to the tenth aspect, wherein in a primary circuit which is a closed circuit having the primary coil, a capacitance of a capacitor connected in series with an end of the primary coil opposite to an end connected to the inverter is equal to 0.1 μF or larger.

A twelfth aspect of the present invention is the evaporation apparatus according to the tenth or eleventh aspect, wherein a value of a resistance component on a secondary side is equal to 20Ω or less.

A thirteenth aspect of the present invention is the evaporation apparatus according to any one of the tenth through twelfth aspects, wherein a value of a resistance component on a secondary side is equal to 0.01Ω or more.

A fourteenth aspect of the present invention is the evaporation apparatus according to any one of the first through thirteenth aspects, further comprising a vacuum chamber; wherein the primary coil is provided outside of the vacuum chamber, and wherein the secondary coil is provided inside the vacuum chamber.

A fifteenth aspect of the present invention is a sublimation purification apparatus configured to purify organic material, comprising a container configured to contain the organic material, at least a portion of which is composed of conductor, a heating coil disposed around the container, a DC power supply, an inverter connected to the DC power supply, a primary coil connected to the inverter, and a secondary coil connected to the heating coil, wherein the primary coil and the secondary coil form a matching transformer.

A sixteenth aspect of the present invention is an organic electronic device production method, using an evaporation apparatus configured to form an organic layer made from organic material on a substrate, wherein the evaporation apparatus comprises a container configured to contain the organic material, at least a portion of which is composed of conductor, a heating coil disposed around the container, a DC power supply, an inverter connected to the DC power supply, a primary coil connected to the inverter; and a secondary coil connected to the heating coil, wherein the primary coil and the secondary coil form a matching transformer, wherein the method includes a conversion step of converting, with the inverter, DC from the DC power supply to AC, a step-down step of stepping down, with the matching transformer, voltage from a side of the primary coil to a side of the secondary coil, and a heating step of heating the container by flowing the alternating current through the coil.

A seventeenth aspect of the present invention is a sublimation purification method using a sublimation purification apparatus configured to purify organic material, wherein the sublimation purification apparatus comprises a container configured to contain the organic material, at least a portion of which is composed of conductor, a heating coil disposed around the container, a DC power supply, an inverter connected to the DC power supply, a primary coil connected to the inverter, and a secondary coil connected to the heating coil, wherein the primary coil and the secondary coil form a matching transformer, wherein the method includes a step-down step of stepping down, with the matching transformer, voltage from a side of the primary coil to a side of the secondary coil. and a heating step of heating the container by flowing the alternating current through the coil.

### Effect of the Invention

According to each aspect of the present invention, by using the matching transformer, it is possible to use different voltages and currents on the primary side and the secondary side. And it is possible to select voltages and currents suitable for the respective applications. Therefore, it is possible to provide a practical evaporation apparatus or the like for suppressing the load of the circuit while flowing a large current by adopting an induction heating method.

Heretofore, since organic substance is more easily vaporized than inorganic substance, it has not been assumed that a large current is passed through a coil to the extent that a matching transformer is used in the production of an organic electronic device. The present invention was conceived as the unique technical thought of using a matching transformer for the organic electronic devices production method, from the viewpoint of reducing the load of circuits, while the inventors worked on the development of organic electronic devices.

In addition, by using a matching transformer, the primary and secondary sides are also thermally shut off. Therefore, it is easy to protect the inverter from the heat of the heating coil which became hot by passing a large current.

Not only high-speed heating but also high-speed cooling are required for the control of the deposition rate. Because the secondary side in the present invention is simply configured comprising the matching transformer, the heating coil, and a capacitor, it is easy to mount a cooling mechanism. This facilitates high-speed heating and high-speed cooling, and becomes easier to control temperature and rate of the container containing the organic material.

Furthermore, as is described later, it was possible to apply power more efficiently while heating when using the matching transformer.

Furthermore, according to the second aspect of the present invention, at a glance, since the cable of the primary side becomes longer, the resistance value component seems to increase the impedance of the circuit and to be disadvantageous on passing a large current. However, according to calculations and experiments in the evaporation apparatus using the induction method by the present inventors, the impedance of the circuit was found to be less susceptible even if the wiring of the primary side is made longer. Moreover, by separating the transformer and the power supply unit through the cable, only the transformer may be placed in a limited space adjacent to the deposition chamber. Therefore, even in a limited space adjacent to the deposition chamber, it is further easier to apply the configuration of the present evaporation apparatus.

Further, according to the third aspect of the present invention, it is possible to step down the voltage from the primary side to the secondary side of the matching transformer. Therefore, it is possible to use a low current although a high voltage on the primary side, and it is easy to work by suppressing the heat generation of the wiring and the circuit on the primary side. Furthermore, since it does not use a large current in the circuit of the primary side, it is possible to suppress failure and loss of control of the inverter or the like due to heat. And there are many products of high-voltage type power MOSEFT, and it is easy to be applied in the circuit construction. Furthermore, in the secondary side, since the current value is increased, it is possible to heat the coil efficiently.

Moreover, the switching loss of the FET is a power loss in the FET and is proportional to the drain current flowing through the FET. Therefore, by not flowing a large current to the circuit of the primary side, the switching loss of the FET is suppressed, resulting in suppressing heat generation in the FET.

Furthermore, according to the fourth aspect of the present invention, by making the secondary side of the matching transfer a resonance circuit, ideally it is possible to flow a large current depending only on the resistance of the coil.

Furthermore, according to the fifth aspect of the present invention, by employing a circuit of the full-bridge system in the primary circuit, the average value of the current flowing through the primary circuit becomes 0. It is possible not to generate DC current, the maximum factor of the load to the circuit such as heat generation in the primary circuit. Therefore, it is possible to suppress the load on the primary circuit while adopting the induction heating system. Moreover, it is possible to apply the total voltage to the primary coil that contributes directly to energy transfer rather than elements that does not directly contribute to energy transfer, such as a capacitor.

Further, according to the sixth aspect of the present invention, by employing a circuit of the half-bridge system in the primary circuit, while the capacitor blocks the DC component, a factor of the load to the circuit such as heat generation, it is possible to transfer energy to the secondary circuit by AC component. Therefore, it is possible to suppress the load on the primary circuit while adopting the induction heating system. Moreover, by changing the capacitance of the capacitor to adjust the impedance of the primary circuit, it is possible to easily adjust the energy input to the primary side.

Furthermore, according to the seventh aspect of the present invention, by shifting the resonance frequencies of the primary circuit and the secondary circuit, it is possible to flow a large current only in the secondary circuit. Therefore, it becomes easy to heat the induction coil efficiently while suppressing the load on the primary circuit such as heat generation in the primary circuit.

Further, according to the eighth and eleventh aspects of the present invention, it is possible to effectively suppress the impedance of the primary side by adjusting the resistance value of the secondary side and the winding density. In terms of an induction type evaporation apparatus or the like, it is a new finding by the present inventors that the resistive component and the winding density among the elements of the secondary side particularly affect the impedance component on the primary side.

Further, according to the ninth aspect of the present invention, it becomes even easier to effectively suppress the impedance component derived from the capacitor on the primary side.

Further, according to the tenth aspect of the present invention, by setting the alternating current supplied to the matching transformer to 200 kHz or more, it is possible to efficiently heat the induction coil. Conventionally, since the inductance of the coil is increased for high frequencies, it has been used only up to about 10-50 kHz. In contrast, in the present invention, by matching the frequency to the resonance frequency of the secondary circuit, it is possible to flow a current in a state where impedance is low even in a high frequency range that has not been used so far.

Furthermore, with respect to the twelfth aspect of the present invention, at first glance, from the viewpoint of improving the efficiency of the induction heating of the transformer system, it seems advantageous to increase the number of turns of the induction coil in order to increase the magnetic flux density. However, according to calculations and experiments in the evaporation apparatus using the induction method by the present inventors, a knowledge that the resistance value of the secondary side particularly affects the impedance was obtained. Therefore, even if the number of turns is reduced, it is easy to suppress the value of the resistance component on the secondary side. In particular, it is easy to smoothly and safely operate even when a large current flows to the device by the resistance value of the secondary side and 20Ω or less.

Furthermore, with respect to the thirteenth aspect of the present invention, when increasing the resistance value of the secondary side, the impedance of the primary side also increases. However, in order to function the induction heating system effectively it is necessary to prepare the number of turns of the coil as one or more. According to calculations and experiments in the evaporation apparatus using the induction method by the present inventors, it is considered necessary to set the resistance value of the secondary side to 0.01Ω or more.

Further, according to the fourteenth aspect of the present invention, it becomes easier to thermally isolate between the primary circuit and the secondary circuit. By reducing the influence of heat from the secondary circuit in the primary circuit to be controlled, it is easy to stabilize the control of the primary circuit and to stabilize the deposition rate when a large current flows. Therefore, it is further facilitated to heat the induction coil efficiently while suppressing the load on the circuit such as heat generation in the primary circuit.

Usually, in order to prevent power loss in a transformer, a common core of the transformer is often used. However, a fourteenth aspect of the present invention has been conceived to provide an evaporation apparatus which efficiently heats an induction coil while suppressing a load on a circuit such as heat generation by separating the core of the transformer.

Moreover, in the secondary circuit, since it is not necessary to draw the conductor of the secondary circuit into the inside from the outside of the vacuum chamber, the seal around the conductor in the flange portion of the vacuum chamber becomes unnecessary. And it is easy to maintain a high degree of vacuum of the vacuum chamber.

Furthermore, by eliminating the spatial constraints due to the cable connected from outside the vacuum chamber, it is easy to move the crucible in the vacuum chamber. Therefore, it is easy to perform the deposition while moving the deposition source.

### BRIEF DESCRIPTION OF THE DRAWINGS

FIG. 1 is an electronic circuit of an induction heating system using an AC power supply and a matching transformer, illustrating a circuit using a full bridge system in the primary circuit.

FIG. 2A illustrates the impedance characteristics of the primary circuit, and FIG. 2B illustrates the impedance characteristic of the secondary circuit.

FIG. 3 is a diagram illustrating an example of the electronic circuit 1, having a resonant circuit on the secondary side.

FIG. 4 is a diagram showing the impedance characteristic of the induction coil and the resonant circuit.

FIG. 5 is a diagram showing an electronic circuit of an induction heating system using an AC power supply and a matching transformer, illustrating an example having a circuit using a half-bridge system in the primary circuit.

FIG. 6 are diagrams showing the results of verification of the effect of heat suppression of circuit with the transformer. FIG. 6A illustrates an outline of the half-bridge circuit in the case of flowing a current directly to the induction coil without using a transformer. FIG. 6B illustrates an outline of the circuit in the case of flowing a current to the induction coil with a transformer. FIG. 6C illustrates an example of heat generation when flowing large current of the same degree to the induction coils in both cases.

FIG. 7 is a schematic diagram illustrating the evaporation apparatus of the present invention in which a matching transformer is installed across the vacuum chamber.

FIG. 8 is a diagram showing a schematic diagram of an evaporation apparatus of the present invention adopting power transmission system by an electric field in addition to the matching transformer.

FIG. 9 is a diagram showing an outline of a configuration of an evaporation apparatus in Example 5.

FIG. 10 are diagrams for comparing the size of the parts to be housed under the chamber. FIG. 10A is a diagram for the case of not using a transformer and FIG. 10B is for the case of using a transformer.

FIG. 11 are graphs illustrating the actually measured influences of inserting the coaxial cable. FIG. 11A is a graph showing the relationship between the switching frequency and the supply current from the DC power supply. FIG. 11B is a graph showing the relationship between the switching frequency and the amplitude of the current induced in the secondary side.

FIG. 12 is a graph illustrating the actually measured influence of inserting the coaxial cable showing the relationship between the switching frequency and the amplitude of the current induced in the primary side.

FIG. 13A is a graph illustrating the change in the current value in the vicinity of the resonance frequency when using the circuit according to the present invention having a transformer. FIG. 13B is a graph illustrating the change in the current value with respect to the frequency of the secondary side when using the circuit according to the present invention having a transformer.

FIG. 14A is a graph illustrating the temporal change of the deposition rate during the film formation using the evaporation apparatus of the induction heating type when the circuit is provided with/without a transformer. FIG. 14B is a graph illustrating the temporal change of the applied power while the temperature rises using the evaporation apparatus of the induction heating type when the circuit is provided with/without a transformer.

FIG. 15 shows a model of a circuit diagram of an induction heating method using a transformer according to the present invention.

FIG. 16 illustrates the consequence of depositing an mCBP which is a host material of the light emitting layer, using the evaporation apparatus of the induction heating type, when the circuit is provided with/without a transformer.

### DETAILED DESCRIPTION

### FORM FOR CARRYING OUT THE INVENTION

### EXAMPLE 1

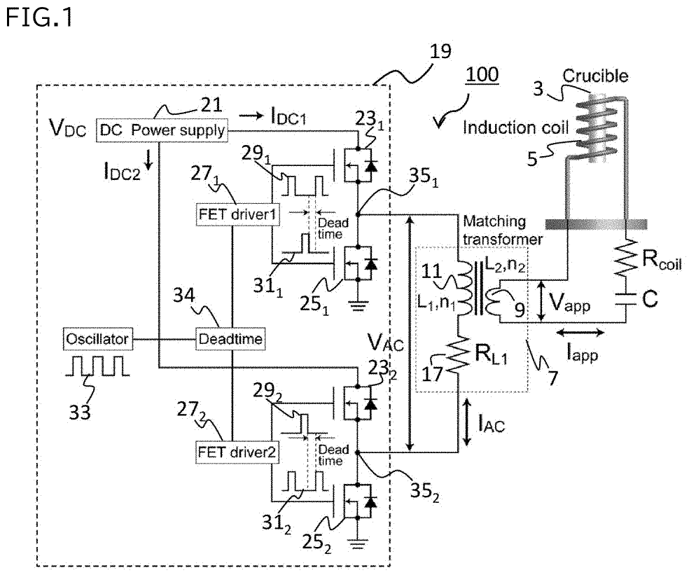

FIG. 1 shows an electronic circuit of an induction heating system using an AC power supply and a matching transformer in the evaporation apparatus, illustrating a circuit using a full bridge system in the primary circuit. Here, in the circuit using the full-bridge method, as described below, both ends of the primary coil is connected to the inverter.

Referring to FIG. 1, in an electronic circuit 100, a silicon power MOSFET23₁ and a silicon power MOSFET25₁ are sequentially connected in series to a DC power source 21 (an example of “DC power source” in the Claims of the present application). A FET drive circuit unit 27₁ is connected to the silicon power MOSFET23₁ and the silicon power MOSFET25₁. The silicon power MOSFET25₁ is grounded on the other side from the point of view of the silicon power MOSFET23₁. Note that regarding both of the silicon power MOSFET23₁ and the silicon power MOSFET25₁, the direction from the side connected toward the DC power source 21 to the side which is grounded is the opposite direction as the transistor, and no current flows in that direction without channels.

The connection point 35₁ between the silicon power MOSFET23₁ and the silicon power MOSFET25₁ is connected to one end of the primary coil 11. Further, the DC power supply 21 is connected to the silicon power MOSFET23₂ and silicon power MOSFET25₂ in series in order. A FET drive circuit unit 27₂ is connected to the silicon power MOSFET23₂ and the silicon power MOSFET25₂. The silicon power MOSFET25₂ is grounded on the other side from the point of view of the silicon power MOSFET23₂. regarding both of the silicon power MOSFET23₂ and the silicon power MOSFET25₂, the direction from the side connected toward the DC power source 21 to the side which is grounded is the opposite direction as the transistor, and no current flows in that direction without channels.

The connection point 35₂ between the silicon power MOSFET23₂ and the silicon power MOSFET25₂ is connected to a resistor 17 which is connected to an end opposite to one end of the primary coil 11 to which the connection point 35₁ is connected.

The heating coil 5 (an example of the “heating coil” in Claims of the present application) installed so as to wrap around the container 3 (an example of the “container” in Claims of the present application) is electrically connected to both ends of the secondary coil 9 (an example of the “secondary coil” in Claims of the present application) of the matching transformer unit 7 (an example of the “conversion transformer” in Claims of the present application). In the matching transformer unit 7, the secondary coil 9 and the primary coil 11 (an example of the “primary coil” in Claims of the present application) is magnetically coupled. The primary side is a circuit that is not a resonant circuit so that a large voltage can be applied without much current flowing. The resistor 17 includes the internal resistance of MOSFET, the resistance of the wire and the primary coil.

Here, the matching transformer unit 7 not only physically but also thermally shuts off the primary circuit and the secondary circuit. Therefore, even when the temperature of the induction coil 5 becomes high, the load on the primary circuit due to heat is cut off. Also, even if the primary circuit becomes high temperature, it is possible to prevent the influence on the secondary circuit.

Further, the winding density of the secondary coil 9 and the primary coil 11 of the matching transformer unit 7 is different. It is possible to make the voltages and currents different between the primary side and the secondary side. Therefore, it is possible to provide a practical evaporation apparatus or the like with reduced heat generation burden on the primary circuit while adopting an induction heating method. The effective voltage V^{R}ₐₚₚ applied to the secondary coil 9 and the effective current I^{R}ₐₚₚ flowing through the secondary coil 9 are expressed by the following equations (3) to (5) using the number of turns n₁ of the primary coil 11, the number of turns n₂ of the secondary coil 9, the voltage V_{AC} applied to the primary coil 11, the resistive component R_{coil} of the inductive coil 5, and the current I_{AC} flowing through the primary coil 11, respectively.

$$[ Equation 3 ]$$

$${V}_{app}^{R} = \frac{{n}_{2}}{{n}_{1}} {V}_{A C}^{R} \qquad ( 3 )$$

$${V}_{A C} = {I}_{app} {R}_{coil} \qquad ( 4 )$$

$${I}_{app}^{R} = \frac{{n}_{1}}{{n}_{2}} {I}_{A C}^{R} \qquad ( 5 )$$

The FET drive circuit unit 27₁ is electronically connected to the gate electrodes of the silicon power MOSFET23₁ and the silicon power MOSFET25₁, respectively. The FET drive circuit unit 27₁ receives a signal from the oscillator 33 and inputs an input signal 29₁ or an input signal 31₁ to the gates of the silicon power MOSFET23₁ or silicon power MOSFET25₁, respectively. Further, the FET driving circuit unit 27₂ is electrically connected to the gate electrodes of the silicon power MOSFET23₂ and the silicon power MOSFET25₂, respectively. The FET drive circuit unit 27₂ receives a signal from the oscillator 33 and inputs an input signal 29₂ or an input signal 31₂ to the gates of the silicon power MOSFET23₂ or silicon power MOSFET25₂, respectively. A dead time providing unit 34 is connected between the oscillator 33 and the FET driving circuit unit 27₁ and the FET driving circuit unit 27₂.

When the input signal 29₁ and the input signal 31₂ are input from the FET drive circuit unit 27₁ and the FET drive circuit unit 27₂ to the silicon power MOSFET 23₁ and the silicon power MOSFET 25₂, respectively, the silicon power MOSFET 23₁ and the silicon power MOSFET 25₂ are turned on. And current flows in the direction of the DC power supply 21, the silicon power MOSFET 23₁, the connection point 35₁, the primary coil 11, the resistor 17, and the silicon power MOSFET 25₂ in order. On the other hand, when the input signal 31₁ and the input signal 29₂ are input from the FET drive circuit unit 27₁ and the FET drive circuit unit 27₂ to the silicon power MOSFET 25₁ and the silicon power MOSFET 23₂, respectively, the silicon power MOSFET 25₁ and the silicon power MOSFET 23₂ are turned on. And current flows in the direction of the silicon power MOSFET23₂, the resistor 17, the primary coil 11, the connection point 35₁, and the silicon power MOSFET25₁ in order. By alternately inputting the input signal 29₁, the input signal 31₂, and the input signal 31₁ and the input signal 29₂, the direct current from the DC power supply 21 can be converted into an alternating current and supplied to the primary coil 11. AC current supplied to the primary coil 11 in the matching transformer unit 7 is transformed in accordance with the winding number ratio between the primary coil 11 and the secondary coil 9 magnetically coupled and is supplied to the induction coil 5.

When switching the input signals, in order to prevent conduction between the silicon power MOSFET23₁ and the silicon power MOSFET25₁ and the conduction of the silicon power MOSFET23₂ and the silicon power MOSFET23₂, the dead time giving unit 34 inserts the dead time before switching.

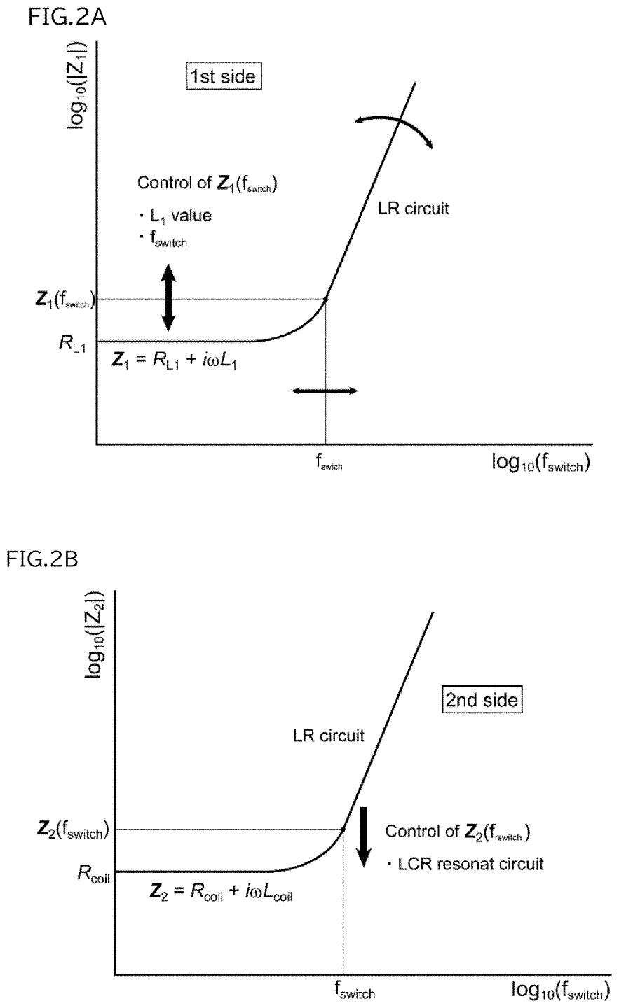

FIG. 2A shows the impedance characteristics of the primary circuit. FIG. 2B shows the impedance characteristics of the secondary circuit. Referring to FIG. 2A, the impedance Z₁ of the primary circuit which is an LR circuit is represented by Z₁=R_{L1}+iωL₁. Therefore, the impedance of the primary circuit depends on the inductances L₁ of the primary coil 11 and the frequency f_{switch} of the current I_{AC}. Further, referring to FIG. 2B, the impedance Z₂ of the secondary circuit which is an LCR circuit is represented by Z₂=R_{coil}+iωL_{coil}. Therefore, the impedance of the secondary circuit depends on the inductances L₂ of the secondary coil 9 and the frequency f_{switch} of the current I_{AC}.

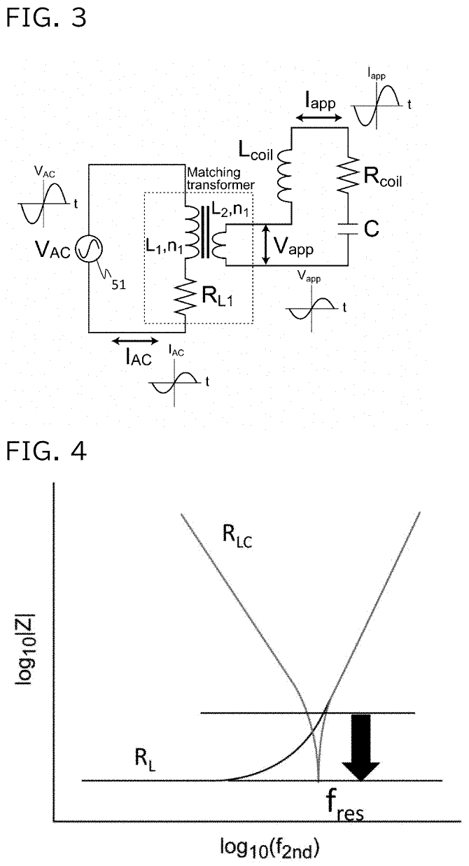

FIG. 3 shows a diagram illustrating an electronic circuit in which the secondary side is a resonant circuit in the electronic circuit 100. In the electronic circuit of FIG. 3, the secondary side of the matching transformer unit 7 is prepared as a resonant circuit. Then, utilizing the characteristics of the resonant circuit, it becomes possible to solve the problem that the current is difficult to flow through the heating coil 5 when increasing the frequency.

Referring to FIG. 3, the primary side of the matching transformer unit 7 is the same with that of the electronic circuit 100 of FIG. 1, although the AC power supply 51 replaces the four MOSFET which realizes AC currents of sin(2πf_{switch} t) by low-pass filtering by L₁. The secondary side of the matching transformer unit 7, a capacitor 39 is added. RLC resonant circuit portion 37 is formed by the secondary coil 9, the induction coil 5, the resistor 41 and the capacitor 39 (an example of the “closed circuit having the secondary coil” in Claims of the present application.) The resistor 41 is the sum of the resistance of the secondary coil 9 and the heating coil 5.

Further, in order to increase the current on the secondary side of the matching transformer unit 7, the primary coil 11 of the matching transformer unit 7 has a larger winding density than the coil 9. With this configuration, it is possible to step down the voltage from the primary side to the secondary side of the matching transformer. Therefore, it becomes possible to use a low current although high voltage on the primary side, and the safety during operation is increased. Furthermore, since it does not use a large current in the circuit of the primary side, it is possible to suppress failure and runaway due to heat of the inverter or the like. And, there are many products of high-voltage type power MOSEFT, and it is easy to construct the circuit. Furthermore, in the secondary side, since the current value is increased, it is possible to heat the coil efficiently.

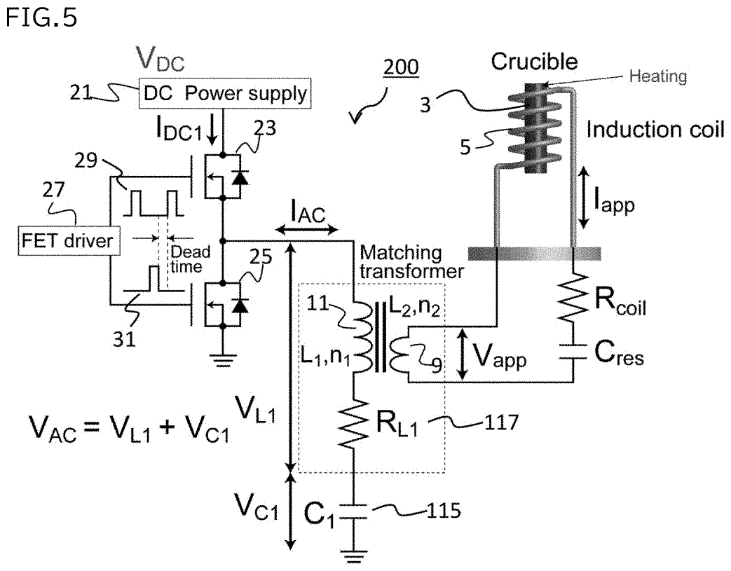

FIG. 4 shows a diagram of the impedance characteristics of the heating coil in the resonant circuit. The impedance is expressed as Z₂=R_{coil}+iωL_{1coil}+1/(iωC). As shown in FIG. 4, when increasing the frequency, it can be seen that the current is hardly flowing to the heating coil 5 rapidly above a specific frequency. In the case where the heating coil 5 is heated by induction heating, the high frequency is preferable. This is because the resistance of the crucible increases due to the skin effect, and the crucible can be efficiently heated using high frequency. Specifically, it may be heated at a high frequency of about 200 KHz or more and 1 MHz or less.

In addition, as shown in FIG. 4, it can be seen that the impedance is greatly reduced at a particular frequency, i.e., the resonance frequency fᵣₑₛ, as the characteristics of the resonance circuits. From this, it is understood that by matching the AC signals on the primary side of the matching transformer unit 7 or the switching frequency of the FET with the resonant frequency fᵣₑₛ on the secondary side, a large current can be flown to the secondary side of the matching transformer unit 7 even at a high frequency such as 200 kHz or more which has not been used so far. Therefore, the evaporation apparatus of this embodiment may be provided with a variable capacitance capacitor.

Further, due to the characteristics of the resonant circuit, it is possible to flow a current depending only on the resistance component of the coil.

By adopting a full-bridge circuit in the primary circuit, the average value of the current flowing through the primary circuit becomes 0. And it is possible not to generate a DC current which is the maximum factor of the load to the circuit such as heat generation in the primary circuit. Therefore, it is possible to suppress the load on the primary circuit while adopting the induction heating system. Moreover, it is also useful in that it is possible to apply the total voltage to the primary coil that contributes directly to the energy transfer, rather than to an element that does not directly contribute to the energy transfer, such as a capacitor.

### EXAMPLE 2

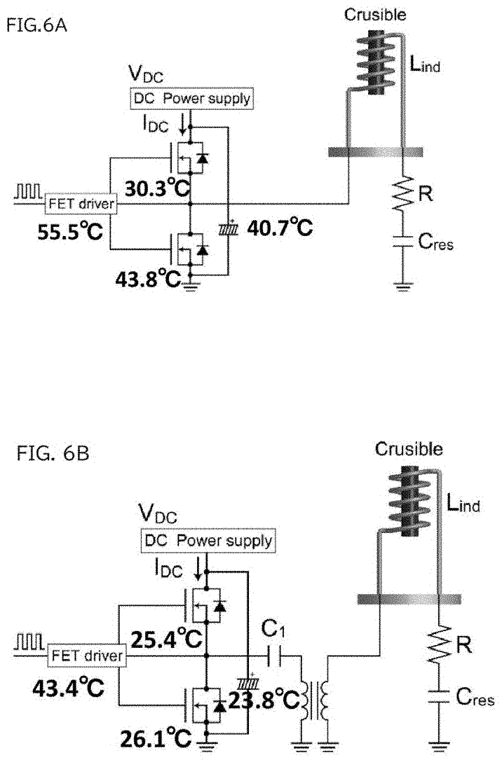

Subsequently, an embodiment using a half-bridge system in the primary circuit will be described. In the circuit using the half-bridge system, one end of the primary coil is connected to the inverter, and the other end is grounded. FIG. 5 shows an electronic circuit of an induction heating system using an AC power supply and a matching transformer. And FIG. 5 is a diagram illustrating an example of a circuit 200 using a half-bridge system in the primary circuit.

Referring to FIG. 5, as a difference between the circuit 100 in FIG. 1 and the circuit 200, the opposite end to the end connected to the connection point 35 of the primary coil 11 in the matching transformer unit 7 is connected to the resistor 117. The opposite end of the resistor 117 when viewed from the primary coil 11 is connected to the capacitor 115. The opposite end of the capacitor 115 when viewed from the resistor 117 is grounded. When the voltage applied to the primary coil 11 and the resistor 117 is represented by V_{L1} and the voltage applied to the capacitor 115 is represented by V_{C1}, the AC voltage V_{AC} applied to the primary coil, the resistor 117, and the capacitor 115 is represented by V_{AC}=V_{L1}+V_{C1}.

By employing a half-bridge circuit in the primary circuit, the capacitor 115 blocks the DC component which is the maximum factor of the load on the circuit, such as heat generation. On the other hand, it becomes possible to transfer energy to the secondary circuit by the AC component. Therefore, it is possible to suppress the load on the primary circuit while adopting the induction heating system. Moreover, by changing the capacitance of the capacitor 115, it is possible to adjust the impedance of the primary circuit and easily adjust the energy input to the primary side.

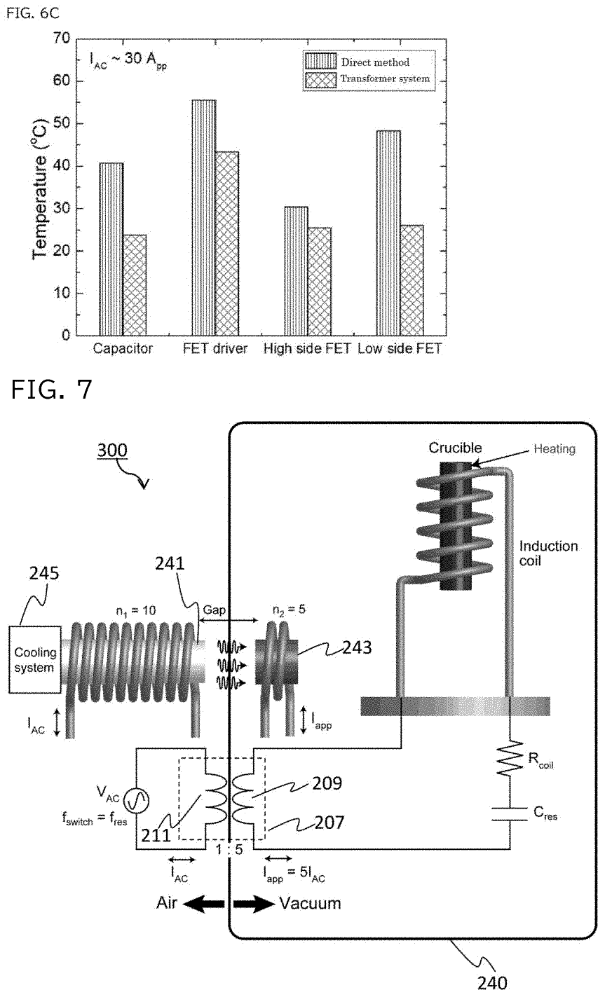

Here, the results of verification of the effect of the transformer to suppress the heat generation of the circuit are shown. FIG. 6A illustrates an outline of the half-bridge circuit in the case of flowing a current directly to the induction coil without using a transformer. FIG. 6B illustrates an outline of the circuit in the case of flowing a current to the induction coil with a transformer. FIG. 6C illustrates an example of heat generation when flowing large current of the same degree to the induction coils in both cases.

When a current of about 30 Aₚₚ was applied to the induction coil in the half-bridge circuit in which a current was directly applied to the induction coil as shown in FIG. 6A, while the room temperature was about 24° C. (degrees Celsius), the DC blocking capacitor in the primary side was 40.7° C., the FET driver was 55.5° C., the high-side FET was 30.3° C., and the low-side FET was raised to 43.8° C.

On the other hand, when a current of about 30 Aₚₚ was applied to the induction coil in the half-bridge circuit using the matching transformer as shown in FIG. 6B, while the room temperature was about 24° C., the DC blocking capacitor in the primary side was 23.8° C., the FET driver was 43.4° C., the high-side FET was 25.4° C., and the low-side FET was 26.1° C. The capacitors, the high-side FET and the low-side FET had almost no temperature rise from room temperature. Although the temperature rise was confirmed for the FET driver, the temperature rise was suppressed by more than 10° C. compared with the case of direct current flow.

FIG. 6C shows a graph summarizing the temperature of each element in the two circuits. Although different types of input noise-filtering (electrolytic) capacitors and FETs were used, the output current was comparable, and the same type of FET drivers were used. It was shown that the transformer system could suppress the temperature rise.

### EXAMPLE 3

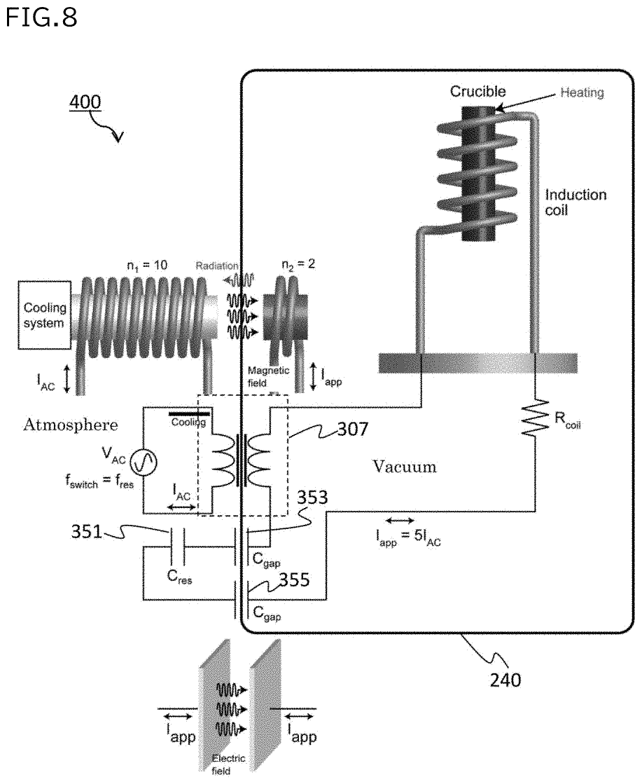

Further, in the present embodiment, a matching transformer is formed through a vacuum chamber. FIG. 7 is a diagram showing a schematic view of an evaporation apparatus 300 provided with a matching transformer 207 through inside and outside the vacuum chamber.

Referring to FIG. 7, a primary circuit having a primary coil 211 is located under atmospheric pressure, and a secondary circuit having a secondary coil 209 is located under vacuum, which is within the vacuum chamber 240 of the evaporation apparatus 300. The primary coil 211 and the secondary coil 209 forms the matching transformer 207. The primary coil 211 has a transformer core 241 made of ferromagnetic material. The secondary coil 209 has a transformer core 243 made of ferromagnetic material.

By the configuration of this embodiment, it is further facilitated to thermally shut off between the primary circuit and the secondary circuit. And by reducing the influence of heat from the secondary circuit in the primary circuit performing the control, it is easy to stabilize the deposition rate when passing a large current.

Here, the control in the primary circuit is described. The frequency of the applied voltage to the matching transformer 207 is controlled using a function generator. The maximum temperature at which the container 3 can reach varies according to the frequency. This means that the heating control becomes possible by controlling the frequency. Further, the maximum temperature at which the container 3 can reach also varies by changing Duty ratio at a constant frequency. This means that the heating control is enabled by Duty ratio control of the square wave to be inputted.

In addition, although only linear control was possible by conventional voltage and current control, nonlinear control becomes possible by frequency control. In the frequency region near the resonant frequency, the maximum reachable temperature changes only slightly compared with the frequency change. Therefore, it is easy to precisely control the temperature. On the other hand, in the frequency region far from the resonant frequency, the maximum reachable temperature greatly changes according to frequency change. Therefore, rapid control is also possible. The relation between Duty ratio and output power becomes linear as well as voltage and current control when controlled at a constant frequency and changing Duty ratio. Though the control signal must be wired to the power supply in the voltage and current control, the control can be done only by changing the setting of the rectangular wave oscillator connected to the inverter in the control of Duty ratio. And the equipment composition can be made compact. By changing the frequency and Duty ratio at the same time, it may be possible to cope with the deposition of organic materials which exhibit complex behavior during deposition, such as a rapid increase in rate and bubbling of material in the crucible during heating.

For example, during film formation by performing deposition in the vicinity of the resonance frequency, it is possible to keep the heating temperature substantially constant even for fluctuations in frequency with changes in circuits in some degree. Therefore, it is possible to precisely control the temperature in the vicinity of the resonance frequency, and it is easy to form films stably.

Furthermore, it will be described in detail below about the configuration of the frequency control unit in the evaporation apparatus. To control the frequency of the alternating current flowing through the coil, as described above, a function generator having good frequency stability may be used. However, such a high-spec device is not necessarily needed for the method for producing an organic electronic device using the evaporation apparatus of the present invention. Moreover, because the function generator is a relatively large device, generation of parasitic capacitance and noise can be a problem.

Therefore, a small oscillator element is used for miniaturization in this embodiment. VCO (Voltage Control Oscillator) an example of small oscillator elements. Since the switching frequency can be adjusted by voltage, it is possible to reduce cable routing and equipment compared with the case of using a function generator.

Further, DDS (Direct Digital Synthesizer) may be used as another small oscillator device. In this case, the digital control makes it easy to stably control. By using a DDS, the setting of Duty ratio can be easily changed from a PID control system such as a microcomputer.

By using small oscillator elements such as VCOs and DDSs, not only AC generation but also a control unit for frequency and Duty ratio (PWM control) control can be miniaturized so that it can be housed in the lower part of the chamber. In particular, as with power semiconductors, the small oscillator element can be installed at a place where the distance from the coil is at least shorter than that from the DC power supply. Preferably by installing the small oscillator element in the lower portion of the chamber, the cable length can be substantially reduced. Therefore, it is easy to suppress the parasitic capacitance and noise generation and the adverse effects on the circuit.

Furthermore, the evaporation apparatus 300 includes a cooling device 245 for cooling the transformer core 241. Thus, even if the transformer core of the matching transformer 207 is separated, the radiation from the transformer core 243 of the secondary coil 209 heated by evaporation, it is possible to efficiently cool the secondary coil.

Further, by cooling the transformer core 241 made of ferromagnetic material, the magnetic permeability is increased, and it is possible to improve the energy transfer efficiency.

### EXAMPLE 4

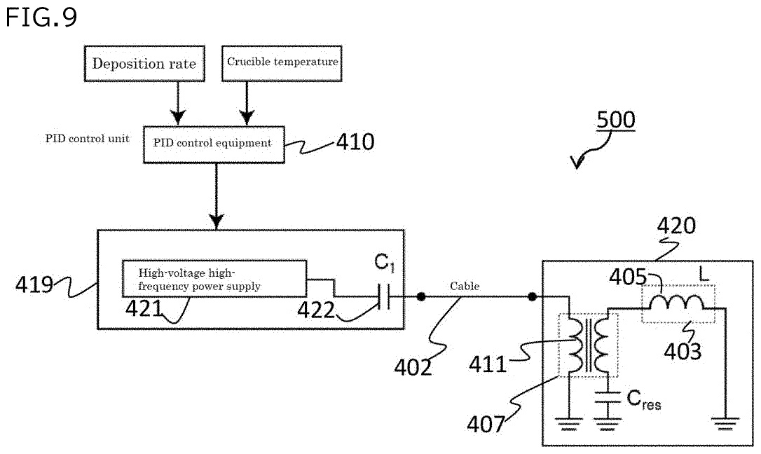

Further, in the present embodiment, a power transmission method using an electric field is also used in combination with the configuration of the third embodiment. FIG. 8 shows a schematic diagram of an evaporation apparatus 400 of the present invention also using power transmission system by electric field in addition to the matching transformer.

Referring to FIG. 8, the evaporation apparatus 400 further comprises transmission capacitors 353 and 355 for energy transmission by electric field, in addition to a matching transformer 307 installed through a vacuum chamber 240 in the same manner as in Example 3. Further, the evaporation apparatus 400 includes a resonant capacitor 351 under atmospheric pressure. The two flat plates of each of transmission capacitors 353 and 355 face each other through the vacuum chamber 240.

In the configuration of this embodiment, by providing the resonance capacitor 351 under atmospheric pressure, it is easy to prepare a capacitor corresponding to the high frequency and large current. Further, it is possible to cool not only the transformer core but also the transmission capacitors 353 and 355 from the atmospheric pressure side, making it possible to improve the cooling efficiency.

### EXAMPLE 5

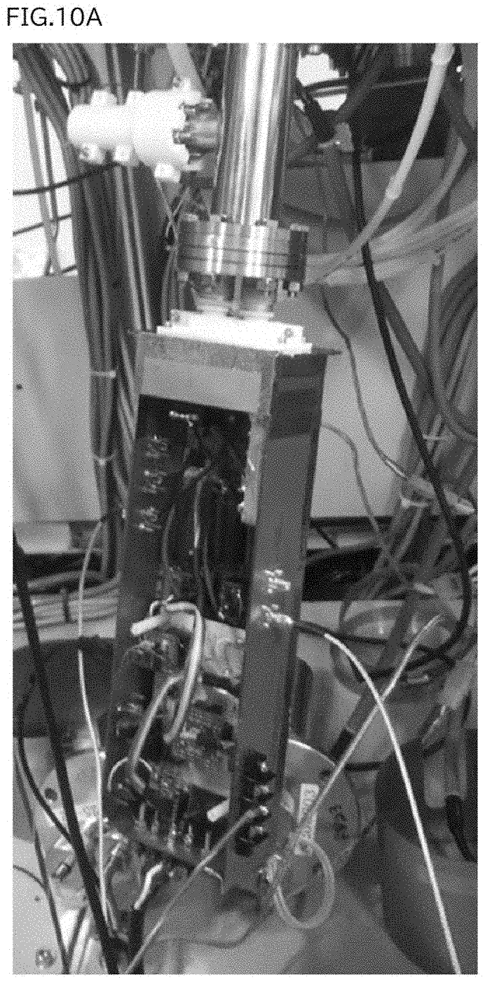

FIG. 9 is a diagram showing an outline of a configuration of an evaporation apparatus in Example 5. In this embodiment, as shown in FIG. 9, the evaporation apparatus is configured so that a matching transformer 407 and a power supply unit 419 is placed away and is connected by a coaxial cable 402. The evaporation apparatus 500 includes a power supply unit 419, a deposition source unit 420, a PID control unit 410. The deposition source unit 420 includes a deposition source 403, an induction coil 405, a vacuum chamber (not shown), a matching transformer 407. Primary coil 411 of the matching transformer 407 is connected to the power supply unit 419 via the coaxial cable 402. The power supply unit 419 includes a high-voltage high-frequency power supply 421 and a capacitor 422 for blocking direct current..

Here, in the limited space of the lower chamber adjacent to the vacuum chamber, only the minimum element including the primary coil 411 is housed basically. The power supply unit 419 and the deposition source unit 420 is connected by the coaxial cable 402. More specifically, the capacitor 422 of the power supply unit 419 and the primary coil 411 of the deposition source unit 420 is connected by the coaxial cable 402. The coaxial cable 402 may be a length according to the size of the evaporation apparatus. Specifically, it will be about 3 to 10 m.

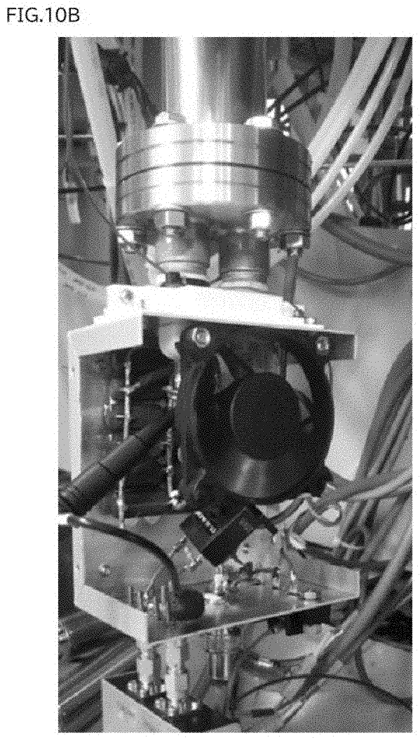

FIG. 10 are diagrams for comparing the size of the parts to be housed under the chamber. FIG. 10A is a diagram for the case of not using a transformer and FIG. 10B is for the case of using a transformer. As can be seen from FIG. 10, when a transformer is used, parts other than the transformer can be installed in a different location, resulting in a large difference in the used volume under the flange.

Here, the effect of inserting the coaxial cable to the primary side on the impedance is described. The present inventors have found that, by setting the value of the capacitance C₁ of the capacitor for blocking direct current on the primary side to an appropriate value, the impedance Z₁ of the circuit is expressed by Equation (6) using the resistance value R₁ of the DC resistance component on the primary side, the resistance value R₂ of the DC resistance component on the secondary side, the number of turns n₁ of the primary coil, and the number of turns n₂ of the secondary coil.

$$[ Equation 4 ]$$

$${Z}_{1} \sim {Z}_{R} = {R}_{1} [ 1 + {( \frac{{n}_{1}}{{n}_{2}} )}^{2} \frac{{R}_{2}}{{R}_{1}} ] \qquad ( 6 )$$

An example of a realistic setting is n₁/n₂=10. Further, when R₁=R₂=1Ω, Z₁=101Ω. This means that when 100V is applied to the primary of the transformer, a current of about 1 A flows. At this time, since n₁/n₂=10, it means that 10V and 10 A AC signals are derived to the secondary side. Since an AC power source generally is converted from 100V or 200V to the DC power source, it is practical to apply 100V to use the AC power source.

Here, when R₁=10Ω, R₂/R₁=0.1, Z₁=110Ω. This means that the impedance Z₁ of the circuit becomes larger only by about 5-10% even if the wire on the primary side is about 5-10 times longer. Likewise, the current induced on the secondary side is reduced only to the same extent. This means that the induced current on the secondary side is less affected by the wiring length on the primary side.

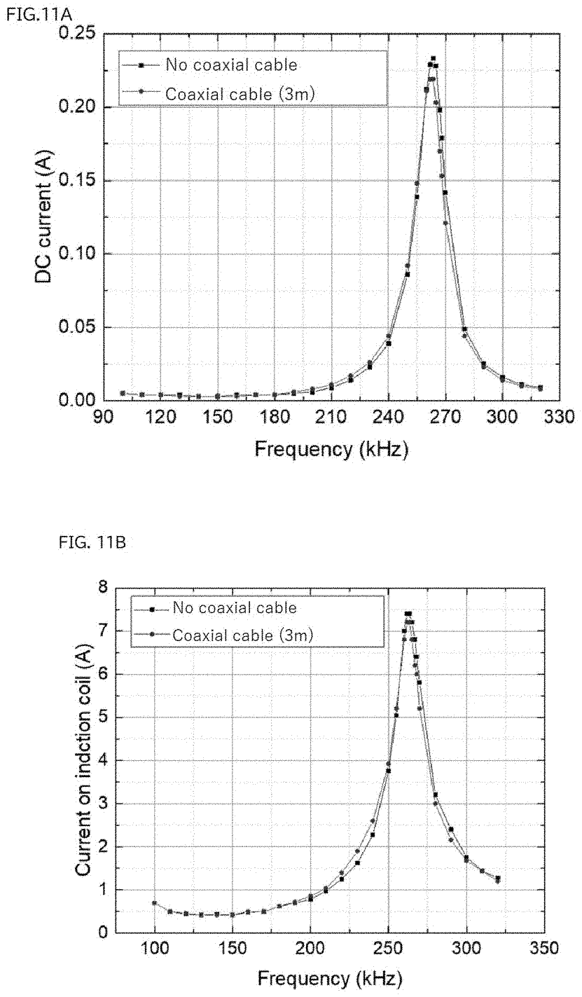

FIG. 11 are graphs illustrating the actually measured influences of inserting the coaxial cable. FIG. 11A is a graph showing the relationship between the switching frequency and the supply current from the DC power supply. FIG. 11B is a graph showing the relationship between the switching frequency and the amplitude of the current induced in the secondary side. As shown in FIG. 11, the current in the vicinity of the resonance frequency of 262 kHz was reduced by only a few % in comparison between the case of direct connection and the case of connection of the power supply unit and the primary coil by the coaxial cable of 3 m. That is, it shows that the effect by extending the cable by inserting the coaxial cable was small, and it supports the above consideration.

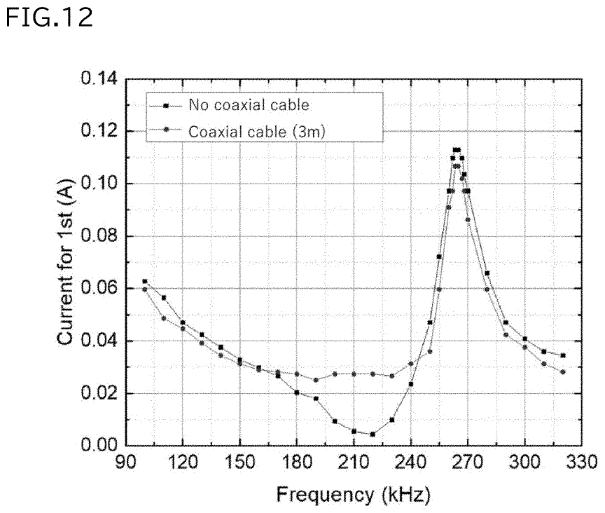

FIG. 12 is a graph illustrating the actually measured influence of inserting the coaxial cable showing the relationship between the switching frequency and the amplitude of the current induced in the primary side. Referring to FIG. 12, in the vicinity of 220 kHz, the amplitude appears larger when a coaxial cable of 3 m is inserted. This is considered to be due in part to a large amount of noise. However, it can be said that the effect of this noise is not meaningful, because induction heating is usually carried out in the vicinity of the resonance frequency. Further, the insertion of the coaxial cable slightly lowers the current value, but does not cause a drop which affects the induction heating.

Here, the numerical range of the resistance value of the secondary side of the transformer is examined. At first glance, from the viewpoint of improving the efficiency of induction heating of the transformer system, it seems that the number of turns of the induction coil may be increased to increase the magnetic flux density. However, according to calculations and experiments in the evaporation apparatus using the induction method by the present inventors, it was found that the resistance value of the secondary side particularly affects the impedance.

For example, if R₁=1Ω, R₂/R₁=10 (R₂=10Ω), Z₁=1001Ω. This means increasing the coil length on the secondary side, that is, increasing the number of turns. Specifically, it is equivalent to lengthening the coil length of the secondary side by about 5-10 times. As the number of turns (R₂) on the secondary side increases, Z₁ is greatly affected and increases, making it difficult for the current to flow to the primary side. As a result, it is also difficult to flow current to the secondary side. At this time, in order to flow a 10 A current to the secondary side, it is required to apply 1000V and a 1 A to the primary side. However, at 1000V, the power supply of 1 A is quite large and dangerous.

Therefore, it is advantageous to suppress the value of the resistance component on the secondary side even by reducing the number of turns. In particular, by making the resistance value of the secondary side 20Ω or less, preferably 15Ω or less, or further preferably 10Ω or less, it is easy to smoothly and safely operate even when a large current to the device.

In principle, there is no limit to the lower limit value of the resistance value on the secondary side. When the resistance value on the secondary side is increased, the impedance on the primary side also increases. However, the number of turns of the coil must be one turn or more in order to make the induction heating system function effectively. According to calculations and experiments in the evaporation apparatus using the induction method by the present inventors, it is considered necessary to set the resistance value of the secondary side to 0.01Ω or more.

Next, the range of the number of turns on the secondary side of the transformer will be examined. As described above, it is necessary to make the number of turns of the coil one or more in order to effectively function the induction heating system. Consider a case where the induction coil is made of copper conductor wire (outer diameter f is 3 mm, number of turns N is 10, and coil length 15 cm) and an alternating current of 300 kHz is flowed. At this time, if the number of turns is increased by 10-20, the resistance value considering the skin effect also increases by 5-10 times, and the resistance value becomes close to the above-mentioned upper limit of R₂.

Therefore, the number of turns N of the induction coil on the secondary side, the range of 1≤N≤30 is appropriate. If you increase the number of turns easily in order to increase the magnetic flux density, there is a possibility that the performance of the transformer cannot be exhibited.

Next, the numerical range of the capacitance C₁ of the capacitor on the primary side is examined. If the capacitance is about 10 times larger than the capacitance shown by the equation (1), it is considered that a sufficiently large current can be obtained on the secondary side. Theoretically, there is no limit to the upper limit, but increasing the capacitance of the capacitor leads to larger size, going away from the realistic configuration. Therefore, in practice, a realistic configuration is possible by setting 20 μF or less, preferably 15 μF or less, and more preferably 10 μF.

Regarding the lower limit of the capacitance C₁ of the capacitance on the primary side, it is better to simply increase C₁, but it is better to make it realistic because the size of the capacitor also increases. For example, when n₁/n₂=10, R₁=R₂=1Ω, the transformer used this time has a specification that allows 30-50 A flow on the secondary side when the frequency is 300 kHz corresponding to the resonant frequency of the I H evaporation source. Considering the use as an evaporation source of the induction heating method, it is considered that setting C₁ of 0.1 μF or more, preferably 0.2 μF or more is considered to be a practical threshold value.

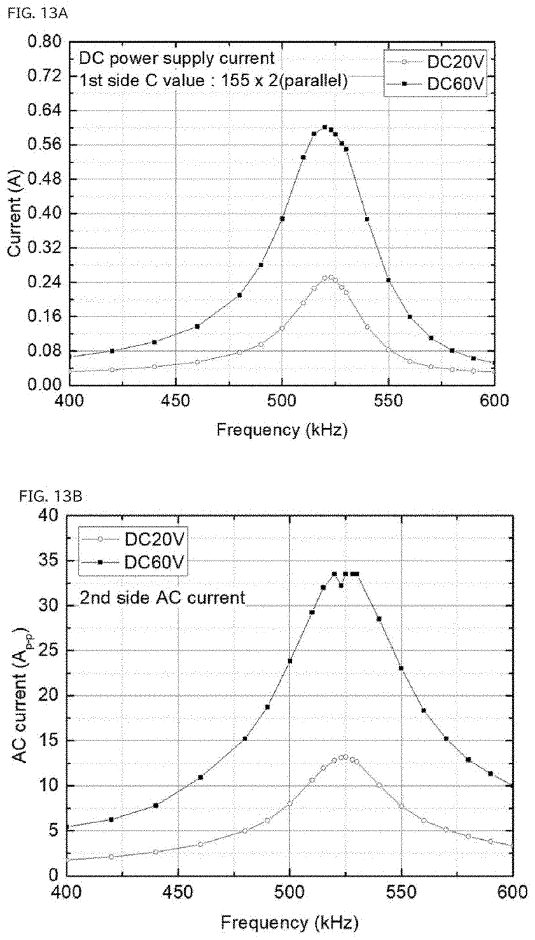

FIG. 13A is a graph illustrating the change in the current value in the vicinity of the resonance frequency when using the circuit according to the present invention having a transformer. FIG. 13B is a graph illustrating the change in the current value with respect to the frequency of the secondary side when using the circuit according to the present invention having a transformer. Referring to FIG. 13, it was actually confirmed that the large current above 10 A was flowed to the secondary side using a circuit having a transformer.

Specifically, as shown in FIGS. 13A and 13B, using a DC power supply of DC20V, when a current of about 0.25 A supplied from a DC power supply having a resonating point near 520 kHz is supplied to the primary side, it was possible to flow an AC current about 13 Aₚₚ having a resonating point in the vicinity as well near 520 kHz on the secondary side. Further, using a DC power supply of DC60V, when a current of about 0.60 A supplied from a DC power supply having a resonating point near 520 kHz is supplied to the primary side, it was possible to flow an AC current about 33 Aₚₚ having a resonating point in the vicinity as well near 520 kHz on the secondary side.

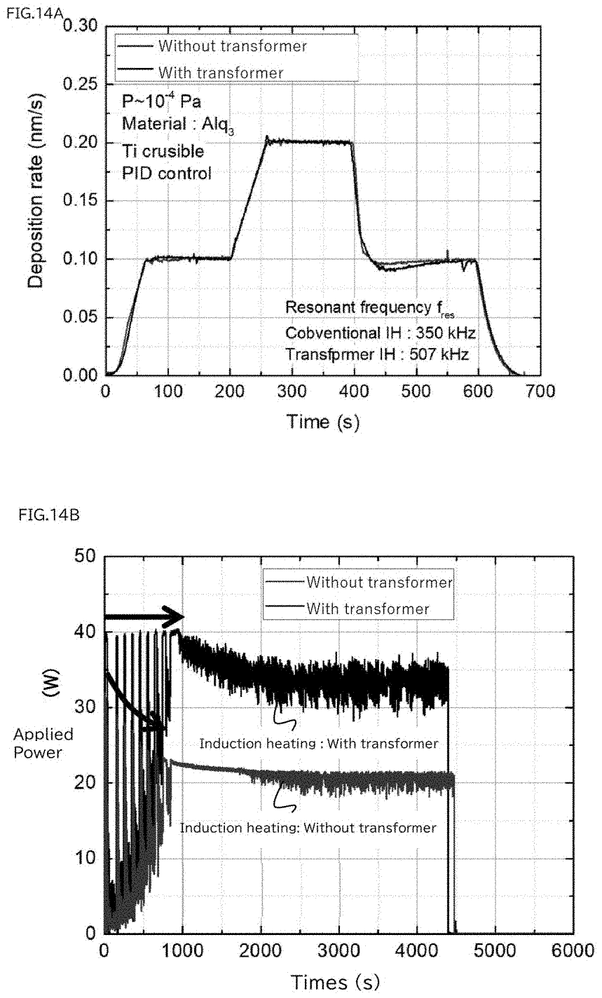

FIG. 14A is a graph illustrating the temporal change of the deposition rate during the film formation using the evaporation apparatus of the induction heating type when the circuit is provided with/without a transformer. FIG. 14B is a graph illustrating the temporal change of the applied power while the temperature rises up to 500° C. using the evaporation apparatus of the induction heating type when the circuit is provided with/without a transformer.

Referring to FIG. 14A, it has been shown that almost no difference in deposition is possible using either a circuit with or without a transformer. The degree of vacuuming at the time of vacuum was about 10⁻⁴ Pa, the used material to form the film was Alq₃, and the crucible was made of titanium. For circuits with and without transformers, the PID control parameters use different numerical values. The resonant frequency was 507 kHz for a circuit with a transformer and 350 kHz for a circuit without a transformer.

Referring to FIG. 14B, in the evaporation apparatus with/without transformer, the way of application of power during heating was found to be different. In the evaporation apparatus without transformer, the power applied at the time of heating up until about 1000 seconds elapsed gradually decreased. On the other hand, in the evaporation apparatus comprising a transformer, the power applied at the time of heating until about 1000 seconds reaching 500° C. was substantially constant. This is considered to be due to the fact that even if a large current flows on the secondary side and the secondary circuit is heated, the effect on the impedance seen from the primary side is smaller than that of the direct method. That is, it has been shown that the induction heating system having a transformer is more efficient in heating even at high temperatures. It is found, by the present inventor, to be possible to technically realize the same film formation rate as in the case where there is no transformer even when the transformer is adopted in the evaporation apparatus of the induction heating type. It is also found, by the present inventor, to be possible to supply power technically and stably for a long time as compared with the direct method at the time of heating.

Further, in the evaporation apparatus with/without a transformer, in the stage where the entire apparatus was warmed and kept at 500° C. stably, the output applied in both of them was almost constant. However, the power required for the evaporation apparatus with a transformer to maintain the temperature was larger.

Here, it is desirable that the electric power does not exceed 50 W as a condition that does not require an application based on Radio Act when the evaporation apparatus according to the present embodiment is used. In the example using the transformer described above, as shown in FIG. 14, the power did not exceed 50 W even during the operation of raising the temperature to 500° C. and maintaining the temperature. The output was sufficient at about 40 W, and the power for the circuit drive was about 1 W. Since there is a margin up to 50 W, the evaporation apparatus with the transformer also satisfies the above conditions.

By adopting transformer configuration, although there is some power loss in the matching transformer, it is possible to compactly configure by suppressing the number of parts in the space adjacent to the vacuum chamber. In addition, since the AC power supply unit is easily incorporated into the system of the entire device, it is easy to keep safe and to monitor. Furthermore, not only because the primary side is less susceptible to heat from the induction coil but also because the primary circuit is less susceptible to heat due to the secondary side heat generation, it is possible to stably supply power for a long time. In addition, from the viewpoint of safety, the transformer system is suitable for supplying a large current to the induction coil. The present inventors have confirmed that 150 W can be provided at least for 40 minutes by an induction heating method using a transformer. At this time, although there was heat generation by the drive, it was possible to stably supply power to the evaporation source.

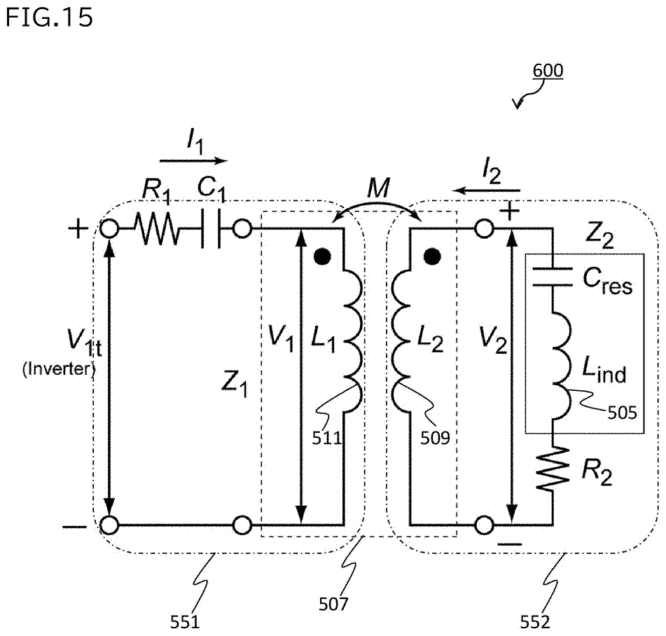

Hereinafter, the process of deriving the equation (6) by the present inventors will be described. FIG. 15 shows a model of a circuit diagram of an induction heating method using a transformer according to the present invention. Referring to FIG. 15, a circuit 600 includes a primary circuit portion 551 in which a resistor (resistance value R₁), a capacitor (capacitance C₁), and a primary coil 511 (inductance L₁) are connected in series, and a secondary circuit portion 552 in which a secondary coil 509 (inductance L₂), a resistor (resistance value R₂), an induction coil 505 (inductance L_{ind}), and a capacitor (capacitance Cᵣₑₛ) are connected in series to form a closed circuit.

The resistance of the resistance R₁ is a resistance component obtained by adding the resistance of the wire on the primary side and the resistance component of the transformer coil on the primary side. The capacitor of capacitance C₁ is used for blocking direct current and is used for adjusting the primary current. The primary-coil 511 of Inductance L₁ form the matching transformer 507 with the secondary coil 509 of Inductance L₂. The resistance of the resistance R₂ is a resistance component obtained by adding the resistance of the secondary side wire, the resistance component of the inductive coil 505, and the resistance component of the secondary coil 509. The capacitor of capacitance Cᵣₑₛ is a secondary resonant capacitor. Let Z₂ be the sum of the impedances of induction coil L_{ind} and the secondary resonating capacitor Cᵣₑₛ.

The impedance Z₁ of the primary coil is expressed by Equation (7) using the mutual inductance M from the combination of the fundamental equation of the transformer and the equation of the Ohm's law. Therefore, the total impedance Zₜ₁ on the primary side is expressed by Equation (8).

$$[ Equation 5 ]$$

$${Z}_{1} = i ω {L}_{1} + \frac{{ω}^{2} {M}^{2}}{i ω {L}_{2} + {Z}_{2} + {R}_{2}} \qquad ( 7 )$$

$$\begin{matrix}{Z}_{t 1} = {R}_{1} + \frac{1}{i ω {C}_{1}} + {Z}_{1} \\ = {R}_{1} + \frac{1}{i ω {C}_{1}} + i ω {L}_{1} + \frac{{ω}^{2} {M}^{2}}{i ω {L}_{2} + {Z}_{2} + {R}_{2}}\end{matrix} \qquad ( 8 )$$

Further, if the frequency is the resonant frequency of the secondary side, the load of the secondary side is only R₂. At this time, the total impedance Zₜ₁ on the primary side is expressed by Equation (9).

$$[ Equation 6 ]$$

$${Z}_{t 1} = {R}_{1} + \frac{1}{i ω {C}_{1}} + i ω {L}_{1} + \frac{{ω}^{2} {M}^{2}}{i ω {L}_{2} + {R}_{2}} \qquad ( 9 )$$

Here, if it is an ideal transformer (k=1) without leakage of magnetic fluxes, M²=k²L₁L₂. Then, the third term and the fourth term on the right side of the equation (9) can be approximated as follows using Taylor expansion. Note that only the first order effect will be discussed assuming that the effects of and after the second order are small enough.

$$[ Equation 7 ]$$

$$i ω {L}_{1} + \frac{{ω}^{2} {L}_{1} {L}_{2}}{i ω ( 1 + \frac{{R}_{2}}{i ω {L}_{2}} )} {1 - {( \frac{{R}_{2}}{ω {L}_{2}} )}^{2} \sim 1}^{\begin{matrix}Be rationalized and the \\ denominator is set at\end{matrix}} \\ ≃ i ω {L}_{1} + \frac{ω {L}_{1}}{i} ( 1 - \frac{{R}_{2}}{i ω {L}_{2}} ) \\ = \frac{{L}_{1}}{{L}_{2}} {R}_{2} \\ = {( \frac{{n}_{1}}{{n}_{2}} )}^{2} {R}_{2} \qquad ( 10 )$$

In the evaporation apparatus of induction heating type, the resonant frequency is assumed to be 200 kHz to 500 kHz, and it is assumed to be sufficiently allowed to approximate as ωL₂>>R₂. Then, the influence of the second term of the equation (9) is also reduced. As a result, Equation (6) is obtained by Equations (9) and (10).

In the above, in Example 5, it has been described adopting a half-bridge, the full-bridge circuit may be adopted. In this case, the capacitance for blocking direct current is not required. This eliminates the need to consider the capacitance C₁. Although the circuit of the FET and the driver is doubled, the load on the circuit when applying a large voltage is reduced by half because the DC voltage to be applied is only half. As a result, it is possible to input twice the power in principle.

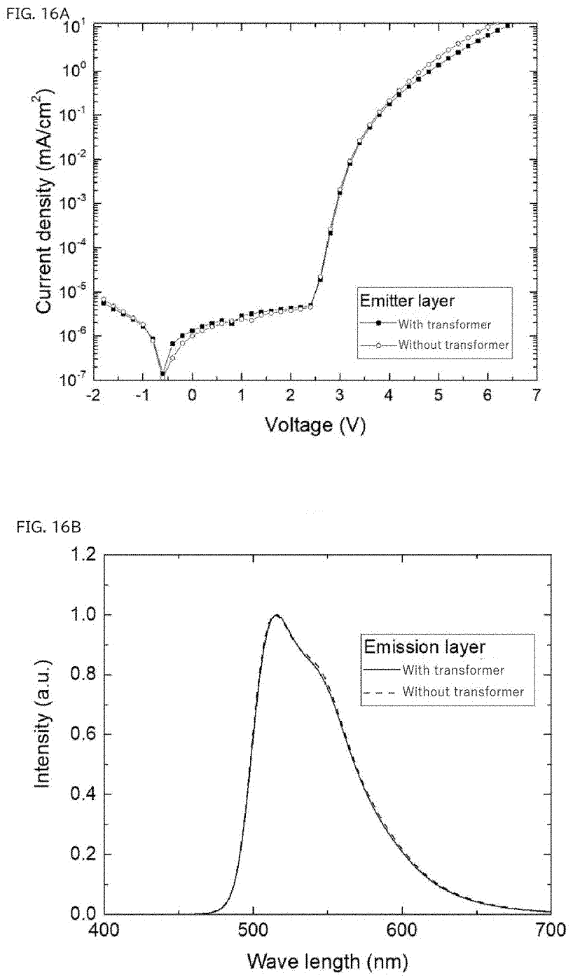

FIG. 16 illustrates the results of the initial characteristics of a phosphorescent organic EL device, using the evaporation apparatus of the induction heating type, when the circuit is provided with/without a transformer. The device structure produced by the evaporation system of the present invention was a device structure of ITO/α-NPD (40 nm)/Ir(ppy)₃ (6 wt %): mCBP (30 nm)/TPBi (50 nm)/LiF (0.8 nm)/Al. Here, ITO (indium tin oxide) is a transparent anode, α-NPD (N,N′-Di(1-naphthyl)-N,N′-diphenylbenzidine) is a hole transport layer, Ir(ppy)₃ (6 wt %): mCBP (3,3′-di(9H-carbazol-9-yl)-1,1′-biphenyl doped with 6 wt % of iridium complex tris(2-phenylpyridinato)iridium(III)) is a light emitting layer, TPBi (1,3,5-tris(1-phenyl1H-benzimidazole-2-yl)benzene)) is an electron transport layer, and LiF/Al is a cathode. Among them, Ir(ppy)₃, which is a doping material of the light emitting layer, was deposited by a circuit without a transformer, and mCBP was deposited by both the circuits with and without a transformer.

Referring to FIG. 16, (a) in the voltage-current density graph, and (b) in the emission spectrum, the circuit with the transformer was able to fabricate a device showing the same characteristics as the device using the circuit without the transformer. External quantum efficiency was about 21% at maximum when no transformer is used, and was as high as about 18% when transformer is used, approaching that without the transformer.

In the above embodiments, silicon-power MOSFETs were used. As long as it is capable of applying a high voltage, other transistors may be used. For example, SiC-MOSFET, IGBT other than silicon-powered MOSFET, or GaN transistors may be used.

Further, the technical feature of providing a matching transformer through inside and outside the vacuum chamber as shown in Example 3 and later is not applicable only to the evaporation apparatus. The present invention is also applicable to devices for transferring energy between the vacuum side and the atmosphere side, such as a sublimation purification device, a thermal balance, and a mass spectrometer. It is also applicable when it is necessary to work under reduced pressure, such as in outboard activities in space.

Here, the cooling method in the vacuum chamber may include, for example, a configuration of a heat bath made of such as copper as a cooling instrument which is placed so that it contacts to the induction coil or the flat plate in the vacuum chamber, and further include a stainless steel bellows pipe directly connected to the heat bath configured to which cooling water flows.

### DESCRIPTION OF THE REFERENCE NUMBERS

(3) container, (5) induction coil, (7) matching transformer unit, (9) secondary coil, (11) primary coil, (13) LCR resonant circuit portion, (15) capacitor, (17) resistor, (19) AC power supply unit, (21) DC power supply unit, (23) silicon power MOSFET, (25) silicon power MOSFET, (27) FET drive circuit, (29) input signal, (31) input signal, (33) oscillator, (34) dead-time applying unit, (35) connection point, (37) RLC resonant circuit portion, (39) capacitor, (41) resistor, (51) AC power supply, (100) electronic circuit (200) electronic circuit

1. An apparatus comprising:
a container configured to contain organic material, at least a portion of which is composed of a conductor;
a heating coil disposed around the container;
a DC power supply;
an inverter connected to the DC power supply;
a primary coil connected to the inverter; and
a secondary coil connected to the heating coil;
wherein the primary coil and the secondary coil form a matching transformer;
wherein the apparatus further comprises a primary circuit, the primary circuit being a closed circuit, the closed circuit comprising the primary coil, the primary circuit comprising a half-bridge type circuit and comprising a capacitor connected in series with the primary coil, and
wherein the capacitor is a DC blocking capacitor.

2. The apparatus according to claim 1, further comprising:
a power supply unit comprising the inverter;
wherein the primary coil is closer to a vacuum chamber of the apparatus than to the power supply unit; and
wherein the power supply unit and the primary coil are connected by a coaxial cable.

3. The apparatus according to claim 1, wherein a winding density of the primary coil is larger than a winding density of the secondary coil.

4. The apparatus according to claim 1, wherein the apparatus further comprises a secondary circuit, the secondary circuit being a closed circuit, the secondary circuit comprising the secondary coil, the secondary circuit being a resonant circuit.

5-6. (canceled)

7. The apparatus according to claim 4, wherein a capacitance of the capacitor is such that a resonant frequency of the primary circuit is different from a resonant frequency of the secondary circuit.

8. The apparatus according to claim 4, wherein the capacitance C₁ of the capacitor is equal to or larger than a value represented by an Equation 1, wherein R₁ is a resistance component of the primary circuit, R₂ is a resistance component of the secondary circuit, ωᵣₑₛ is a resonant angular frequency of the secondary circuit, n₁ is a number of turns of the primary coil, and n₂ is a number of turns of the secondary coil.
$$[ Equation 1 ]$$
$${C}_{1} = {{ω}_{res}^{- 1} [ {R}_{1} + {( \frac{{n}_{1}}{{n}_{2}} )}^{2} {R}_{2} ]}^{- 1} \qquad ( 1 )$$

9. The evaporation apparatus according to claim 4, wherein the resonant angular frequency ωᵣₑₛ of the secondary circuit is equal to or larger than a value represented by an Equation 2, wherein C₁ is the capacitance of the capacitor, R₁ is a resistance component of the primary circuit, R₂ is a resistance component of the secondary circuit, n₁ is a number of turns of the primary coil, and n₂ is a number of turns of the secondary coil.
$$[ Equation 2 ]$$
$${ω}_{res} = {{C}_{1}^{- 1} [ {R}_{1} + {( \frac{{n}_{1}}{{n}_{2}} )}^{2} {R}_{2} ]}^{- 1} \qquad ( 2 )$$

10. The apparatus according to claim 1, wherein an alternating current supplied to the matching transformer has a high frequency of 200 kHz or more.

11. The apparatus according to claim 10, wherein in the primary circuit a capacitance of a capacitor connected in series with an end of the primary coil opposite to an end connected to the inverter is equal to 0.1 μF or larger.

12. The apparatus according to claim 10, wherein a value of a resistance component on a secondary side is equal to 20Ω or less.

13. The apparatus according to claim 10, wherein a value of a resistance component on a secondary side is equal to 0.01Ω or more.

14. An apparatus comprising:
a container configured to contain organic material, at least a portion of which is composed of a conductor;
a heating coil disposed around the container;
a DC power supply;
an inverter connected to the DC power supply;
a primary coil connected to the inverter;
a secondary coil connected to the heating coil; and
a vacuum chamber;
wherein the primary coil is provided outside of the vacuum chamber,
wherein the secondary coil is provided inside the vacuum chamber, and
wherein the primary coil and the secondary coil form a matching transformer.

15. (canceled)

16. A method of using an apparatus,
wherein the evaporation apparatus comprises;
a container configured to contain organic material, at least a portion of which is composed of a conductor;
a heating coil disposed around the container;
a DC power supply;
an inverter connected to the DC power supply;
a primary coil connected to the inverter; and
a secondary coil connected to the heating coil;
wherein the primary coil and the secondary coil form a matching transformer;
wherein a primary circuit which is a closed circuit having the primary coil is a half-bridge type circuit, having a capacitor connected to the primary coil in series;
wherein the capacitor is a DC blocking capacitor; and
wherein the method includes:
converting, with the inverter, direct current from the DC power supply to alternating current;
stepping down, with the matching transformer, voltage from a side of the primary coil to a side of the secondary coil; and
heating the container by flowing the alternating current through the heating coil.

17. A method of using an apparatus,
wherein the apparatus comprises:
a container configured to contain organic material, at least a portion of which is composed of a conductor;
a heating coil disposed around the container;
a DC power supply;
an inverter connected to the DC power supply;
a primary coil connected to the inverter;
a secondary coil connected to the heating coil; and
a vacuum chamber;
wherein the primary coil is provided outside of the vacuum chamber,
wherein the secondary coil is provided inside the vacuum chamber, and
wherein the primary coil and the secondary coil form a matching transformer; and
wherein the method includes:
converting, with the inverter, direct current from the DC power supply to alternating current;
stepping down, with the matching transformer, voltage from a side of the primary coil to a side of the secondary coil; and
heating the container by flowing the alternating current through the heating coil.
